(19) United States
(12) Patent Application Publication
(10) Pub. No.: US 2026/0068206 A1
(43) Pub. Date: Mar. 5, 2026

(54) METHOD OF MANUFACTURING SEMICONDUCTOR DEVICE

(71) Applicant: FUJI ELECTRIC CO., LTD., Kawasaki-shi (JP)

(72) Inventors: Shunsuke TANAKA, Matsumoto-city (JP); Kohichi HASHIMOTO, Matsumoto-city (JP)

(73) Assignee: FUJI ELECTRIC CO., LTD., Kawasaki-shi (JP)

(21) Appl. No.: 19/251,428

(22) Filed: Jun. 26, 2025

(30) Foreign Application Priority Data
Aug. 30, 2024 (JP) 2024-149867

(51) Int. Cl. H10D 30/01; H01L 21/02; H01L 21/04; H10D 30/66; H10D 62/832; H10D 64/66

(52) U.S. Cl. CPC H10D 30/0297; H10D 62/8325; H10D 64/661; H10D 30/668

(57) ABSTRACT

A method of manufacturing a semiconductor device includes: preparing semiconductor substrate having a front surface and a back surface opposite to each other, the semiconductor substrate being of a first conductivity type; forming a device structure in the semiconductor substrate, at the front surface; performing thermal oxidation to form a gate insulating film and depositing a polysilicon to form a plurality of gate electrodes; removing the polysilicon at the back surface of the semiconductor substrate while leaving an oxide film formed at the back surface and a side surface of the semiconductor substrate by the thermal oxidation; forming a surface electrode on the device structure; and forming a plating film on the surface electrode while continuing to leave the oxide film at the back surface and the side surface of the semiconductor substrate.

### CROSS REFERENCE TO RELATED APPLICATIONS

This application is based upon and claims the benefit of priority of the prior Japanese Patent Application No. 2024-149867, filed on Aug. 30, 2024, the entire contents of which are incorporated herein by reference.

### BACKGROUND OF THE INVENTION

### 1. Field of the Invention

Embodiments of the disclosure relate to a method of manufacturing a semiconductor device.

### 2. Description of the Related Art

Conventionally, during Ni/Au electroless plating treatment of SiC, to prevent plating deposition other than at a surface of an Al—Si electrode where plating is intended to be formed, there is a method of manufacturing a semiconductor device in which such plating deposition is prevented by using a back-surface tape and outer peripheral tape when a plating treatment is performed (for example, Japanese Laid-Open Patent Publication No. 2011-222898 and Japanese Laid-Open Patent Publication No. 2014-86667).

### SUMMARY OF THE INVENTION

According to an embodiment of the disclosure, a method of manufacturing a semiconductor device, includes: preparing a semiconductor substrate having a front surface and a back surface opposite to each other, the semiconductor substrate being of a first conductivity type; forming a device structure in the semiconductor substrate at the front surface; performing thermal oxidation on the semiconductor substrate to form a gate insulating film and depositing a polysilicon on the semiconductor substrate to form a plurality of gate electrodes; removing the polysilicon at the back surface of the semiconductor substrate while leaving an oxide film formed at the back surface and a side surface of the semiconductor substrate by the thermal oxidation; forming a surface electrode on the device structure; and forming a plating film on the surface electrode while continuing to leave the oxide film at the back surface and the side surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional diagram depicting an active structure of a silicon carbide semiconductor device according to an embodiment.

FIG. 2 is a flowchart of a method of manufacturing the silicon carbide semiconductor device according to the embodiment.

FIG. 3 is a cross-sectional view depicting a state of the semiconductor device according to the embodiment during manufacture.

FIG. 4 is a cross-sectional view depicting a state of the semiconductor device according to the embodiment during manufacture.

FIG. 5 is a cross-sectional view depicting a state of the semiconductor device according to the embodiment during manufacture.

FIG. 6 is a cross-sectional view depicting a state of the semiconductor device according to the embodiment during manufacture.

FIG. 7 is a cross-sectional view depicting a state of the semiconductor device according to the embodiment during manufacture.

FIG. 8 is a flowchart depicting a method of manufacturing a conventional semiconductor device.

FIG. 9 is a cross-sectional view schematically depicting a state of the conventional semiconductor device during manufacture.

FIG. 10 is a cross-sectional view schematically depicting a state of the conventional semiconductor device during manufacture.

FIG. 11 is a cross-sectional view schematically depicting a state of the conventional semiconductor device during manufacture.

FIG. 12 is a cross-sectional view schematically depicting a state of the conventional semiconductor device during manufacture.

FIG. 13 is a cross-sectional view schematically depicting a state of the conventional semiconductor device during manufacture.

FIG. 14 is a cross-sectional view schematically depicting a state of the conventional semiconductor device during manufacture.

### DETAILED DESCRIPTION OF THE INVENTION

First, problems associated with the conventional techniques are discussed. In the method of manufacturing a conventional semiconductor device, labor for applying and removing the back-surface tape and the outer peripheral tape as well as tape material costs are incurred. A further problem arises in that when a subsequent manufacturing process is performed with the back-surface tape and or adhesive of the outer peripheral tape still attached, defects occur at the subsequent manufacturing process.

An outline of an embodiment of the present disclosure is described. A method of manufacturing a semiconductor device solving the problems above and achieving an object has the following features. First, a first process for forming a device structure at a front surface of a semiconductor substrate of a first conductivity type is performed. Next, a second process for performing thermal oxidation to thereby form a gate insulating film and depositing a polysilicon to thereby form gate electrodes is performed. Next, a third process for leaving an oxide film formed by the thermal oxidation at a side surface and a back surface of the semiconductor substrate and removing the polysilicon at the back surface of the semiconductor substrate is performed. Next, a fourth process for forming a surface electrode on the device structure is performed. Next, a fifth process for leaving the oxide film at the back surface and the side surface of the semiconductor substrate and depositing a plating film on the surface electrode is performed.

According to the disclosure above, the plating film is formed with the oxide film left at the back surface and the side surface of the silicon carbide substrate to prevent plating deposition thereat. As a result, no plating film is formed at exposed SiC portions of the silicon carbide substrate. Thus, protection of the back surface and the side surface using tape during plating becomes unnecessary, thereby enabling labor and material costs to be reduced.

Further, the method of manufacturing the semiconductor device according to the present disclosure, in the disclosure above, further includes a sixth process for removing the oxide film at the back surface and the side surface of the semiconductor substrate after the fifth process.

Further, in the method of manufacturing the semiconductor device according to the present disclosure, in the disclosure above, a thickness of the oxide film at the back surface and the side surface of the semiconductor substrate is at least 50 nm but not more than 1000 nm.

Further, in the method of manufacturing the semiconductor device according to the present disclosure, in the disclosure above, in the third process, the polysilicon at the back surface of the semiconductor substrate is removed by dry etching and selectivity (etch rate of polysilicon/etch rate of SiO₂) in the dry etching is at least 4.5 but not more than 5.5.

Further, in the method of manufacturing the semiconductor device according to the present disclosure, in the disclosure above, in the fifth process, a nickel (Ni) plating film and a gold (Au) plating film are formed as a plating film using an electroless plating process.

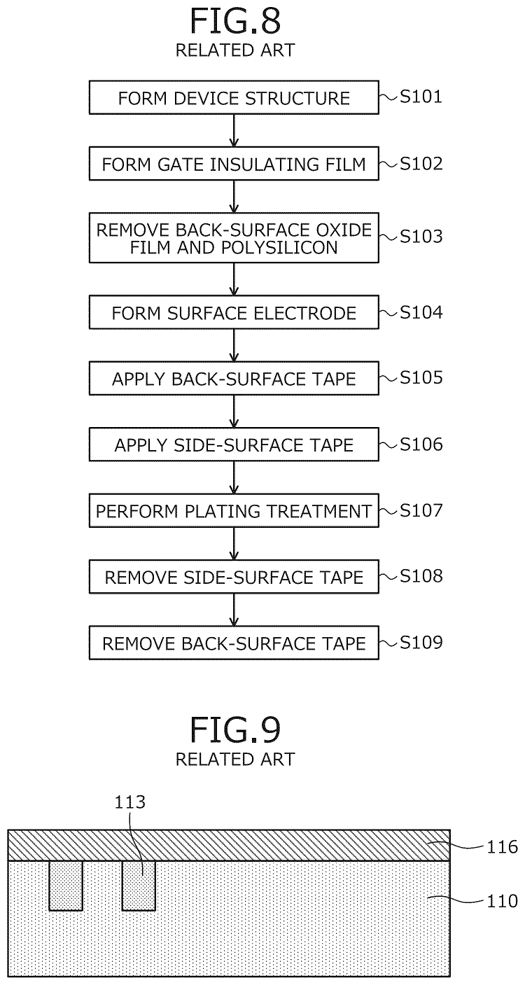

Findings underlying the present disclosure are discussed. Here, problems associated with the method of manufacturing a conventional semiconductor device are discussed. FIG. 8 is a flowchart depicting the method of manufacturing a conventional semiconductor device. FIGS. 9, 10, 11, 12, 13, and 14 are cross-sectional views schematically depicting states of the conventional semiconductor device during manufacture. In the method of manufacturing the conventional semiconductor device, first, a device structure formed by an n⁻type drift region, a p-type base region, p⁺⁺-type contract regions, and n⁺⁺-type source regions, etc. is formed in a silicon carbide substrate 110 (step S101). Next, a gate insulating film is formed by thermal oxidation and gate electrodes 113 are formed by depositing a polysilicon (poly-si) (step S102). Next, an oxide film at the back surface and the polysilicon at the back surface formed, respectively, by the thermal oxidation and the deposition of the polysilicon are removed (step S103). Next, an Al—Si film 116 constituting a surface electrode is formed by a sputtering method or the like (step S104). The state up to here is depicted in FIG. 9.

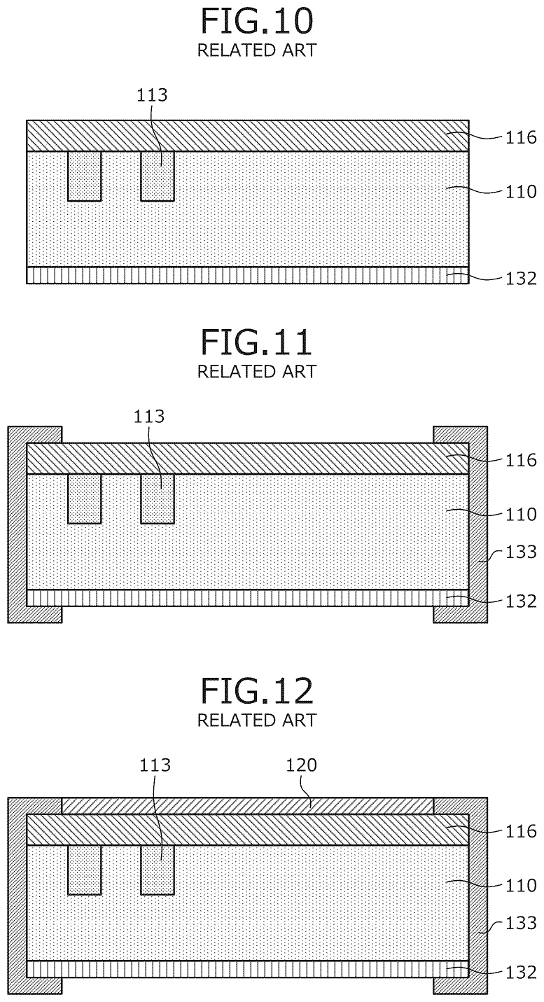

Next, a back-surface tape 132 is applied to an entire area of the back surface of the silicon carbide substrate 110 (step S105). The state up to here is depicted in FIG. 10. Next, a side-surface tape 133 is applied to an outer peripheral portion of the silicon carbide substrate 110 (step S106). The state up to here is depicted in FIG. 11.

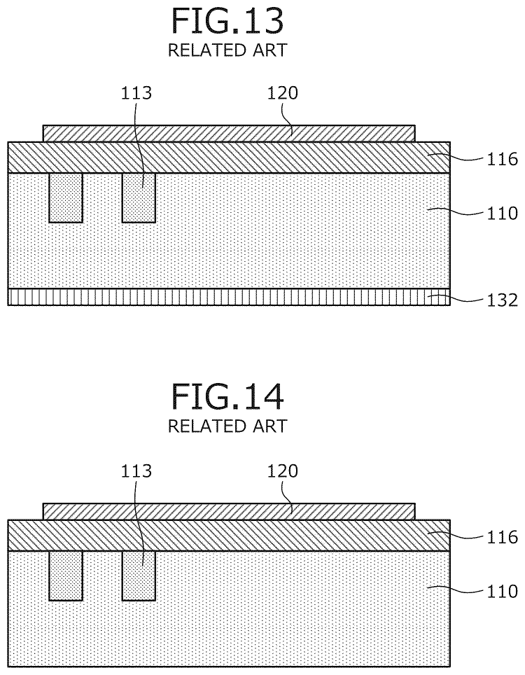

Next, a nickel (Ni) plating layer is deposited in an entire area of the front surface of the silicon carbide substrate 110 and thereafter, a gold (Au) plating layer is stacked on the entire surface of the nickel-plating layer, thereby forming a plating film 120 (step S107). The state up to here is depicted in FIG. 12. Next, the side-surface tape 133 is removed from the outer peripheral portion of the silicon carbide substrate 110 (step S108). The state up to here is depicted in FIG. 13. Next, the back-surface tape 132 is removed from the silicon carbide substrate 110 (step S109). The state up to here is depicted in FIG. 14. In an instance in which, for example, an ultraviolet (UV) film is used as the back-surface tape 132 and the side-surface tape 133, the back-surface tape 132 and the side-surface tape 133 may be removed by irradiating UV light.

When the nickel (Ni)/gold (Au) electroless plating treatment is performed to the silicon carbide (SiC) portions as is, a Ni/Au film with poor adhesion is formed and this film may fall into the plating treatment tank, whereby the life of the plating treatment tank may be shortened and plating quality may decrease, for example, abnormalities in the plating deposition may occur. Thus, conventionally, during Ni/Au electroless plating treatment of SiC, to prevent plating deposition other than at a surface Al—Si electrode intended for plating, the back-surface tape 132 and the outer peripheral tape 133 are used, a plating treatment is performed and ultraviolet (UV) rays are irradiated, and the plating the back-surface tape 132 and the outer peripheral tape 133 are removed thereafter.

However, in the method of manufacturing the conventional semiconductor device, a problem arises in that labor for applying and removing the back-surface tape 132 and the outer peripheral tape 133 and material costs for the back-surface tape 132 and the outer peripheral tape 133 are incurred when the back surface and the side surface are protected using the tape. Furthermore, when a subsequent process proceeds with adhesive of the outer peripheral tape 133 attached as is, a problem arises in that a defect occurs in that an error occurs caused by a height difference during glass mounting of a wafer support system (WSS). A further problem arises in that the subsequent process proceeds with the back-surface tape 132 adhered as is and during testing, a defect occurs in which conduction cannot be obtained and electrical characteristics cannot be measured.

Embodiments of a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

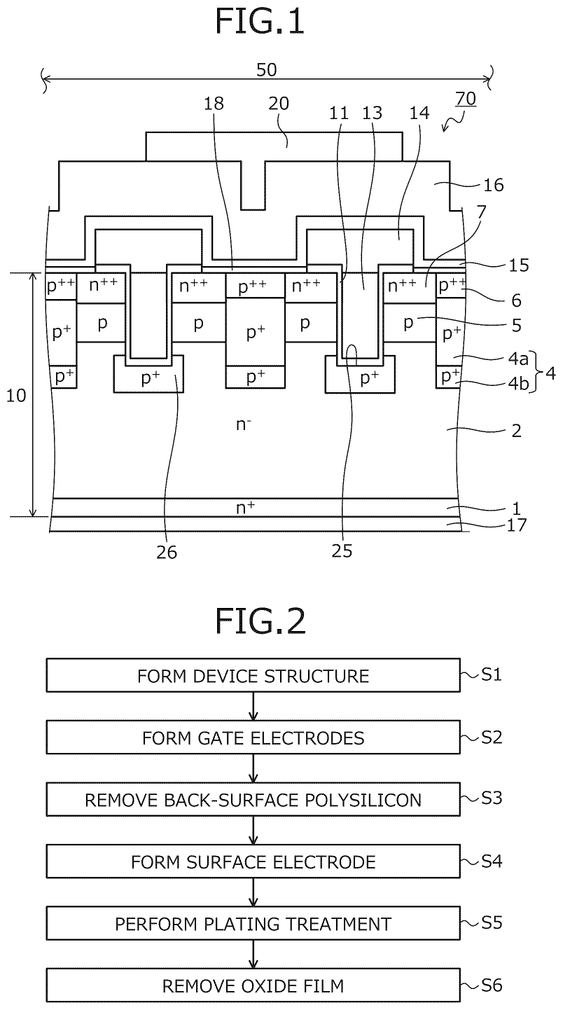

A semiconductor device according to the present disclosure contains a wide band gap semiconductor. In an embodiment, a silicon carbide semiconductor device fabricated using, for example, silicon carbide (SiC) as a wide band gap semiconductor is described taking a metal oxide semiconductor field effect transistor (MOSFET) as an example. FIG. 1 is a cross-sectional diagram depicting an active structure of the silicon carbide semiconductor device according to the embodiment.

The silicon carbide semiconductor device 70 according to the embodiment includes a semiconductor substrate (hereinafter, silicon carbide substrate (semiconductor substrate (semiconductor chip))) containing silicon carbide and in which an active region 50 and an edge termination region (not depicted) surrounding a periphery of the active region 50 are provided. The active region 50 is a region through which a current flows during an on-state. The edge termination region is a region that relaxes electric field of a front side of a drift region and sustains a breakdown voltage.

As depicted in FIG. 1, in the silicon carbide substrate, an n⁻-type drift region 2 containing silicon carbide and having a first surface and a second surface opposite to each other is provided with the second surface being at a front surface of an n⁺-type starting substrate (an n⁺-type silicon carbide substrate, a semiconductor substrate of a first conductivity type) 1 containing silicon carbide, and a p-type base region 5 containing silicon carbide is provided at the first surface of the n⁻-type drift region 2. The n⁺-type silicon carbide substrate 1 functions as a drain region. Further, between the n⁻-type drift region 2 and the n⁺-type silicon carbide substrate 1, for example, a buffer layer or the like that reduces the growth of crystal defects from the n⁺-type silicon carbide substrate 1 may be provided.

The n⁺-type silicon carbide substrate 1 is a single crystal silicon carbide substrate. The n⁻-type drift region 2 has a dopant concentration that is lower than a dopant concentration of the n⁺-type silicon carbide substrate 1. The n⁻-type drift region 2 reaches the p-type base region 5, is in contact with the p-type base region 5 and later-described p⁺-type partial regions 4, reaches later-described trenches 25 in a direction parallel to the front surface of the semiconductor substrate, and is in contact with a gate insulating film 11. The dopant concentration of the n⁻-type drift region 2 is, for example, not more than 5×10¹⁶ cm⁻³ and a thickness of the n⁻-type drift region 2 is 5.0 μm or more.

Further, between the n⁻-type drift region 2 and the p-type base region 5, an n-type high-concentration region (not depicted) may be provided. In an instance in which an n-type high-concentration region is provided, the n-type high-concentration region is in contact with later-described adjacent ones of the p⁺-type partial regions 4 and extends in directions parallel to the front surface of the semiconductor substrate to reach the trenches 25 and be in contact with the gate insulating film 11. The n-type high-concentration region has an upper surface in contact with the p-type base region 5 and a lower surface in contact with the n⁻-type drift region 2. A dopant concentration of the n-type high-concentration region is lower than the dopant concentration of the n⁺-type silicon carbide substrate 1 and higher than the dopant concentration of the n⁻-type drift region 2.

At a second main surface (back surface, i.e., the back surface of the silicon carbide substrate) of the n⁺-type silicon carbide substrate 1, a drain electrode 17 constituting a back electrode is provided. At a surface of the drain electrode 17, a drain electrode pad (not depicted) is provided.

In the silicon carbide substrate, a trench structure is provided at a first main surface (side having the p-type base region 5). In particular, the trenches 25 penetrate through the p-type base region 5 from a first surface (surface facing the first main surface of the silicon carbide substrate) of the p-type base region 5, opposite to a second surface thereof facing the n⁺-type silicon carbide substrate 1, the trenches 25 reaching the n⁻-type drift region 2 (in an instance in which the n-type high-concentration region is provided, the n-type high-concentration region).

Along inner walls of the trenches 25, the gate insulating film 11 is formed at sidewalls and a bottom of each of the trenches 25, and gate electrodes 13 are formed on the gate insulating film 11 in the trenches 25. The gate insulating film 11 electrically insulates the gate electrodes 13 from the n⁻-type drift region 2 and the p-type base region 5. A portion of each of the gate electrodes 13 may protrude from a top (side facing a later-described source electrode pad 16) thereof in a direction to the source electrode pad 16.

The n⁻-type drift region 2, at the first surface thereof facing the first main surface of the silicon carbide substrate, has a surface layer and in the surface layer, upper p⁺-type partial regions 4a are provided. The upper p⁺-type partial regions 4a, for example, are provided between the trenches 25. Further, in the n⁻-type drift region 2, lower p⁺-type partial regions 4b in contact with bottoms of the upper p⁺-type partial regions 4a are provided. Further, at bottoms of the trenches 25, p⁺-type regions 26 are provided. The p⁺-type regions 26 in contact with the bottoms of the trenches 25 are provided at positions facing the bottoms of the trenches 25 in a depth direction (direction from the source electrode pad 16 to the back electrode). The upper p⁺-type partial regions 4a and the lower p⁺-type partial regions 4b between the trenches 25 collectively constitute the p⁺-type partial regions 4.

A width of each of the p⁺-type regions 26 is a same or wider than a width of each of the trenches 25. Further, a width of each of the lower p⁺-type partial regions 4b is a same or wider than a width of each of the upper p⁺-type partial regions 4a. The bottoms of the trenches 25 may reach the p⁺-type regions 26 or may be positioned in the n⁻-type drift region 2, sandwiched between the p-type base region 5 and the p⁺-type regions 26.

In the p-type base region 5, at the first surface thereof (the first main surface of the silicon carbide substrate), n⁺⁺-type source regions 7 and p⁺⁺-type contact regions 6 are selectively provided. Further, the n⁺⁺-type source regions 7 and the p⁺⁺-type contact regions 6 are in contact with each other.

An interlayer insulating film 14 is provided in an entire area of the first main surface of the silicon carbide substrate so as to cover the gate electrodes 13 embedded in the trenches 25. The interlayer insulating film 14 contains NSG or BPSG. The interlayer insulating film 14 has contact holes and at bottoms of the contact holes, source electrodes 18 in contact with the n⁺⁺-type source regions 7 and the p⁺⁺-type contact regions 6 are provided. The source electrodes 18 are in contact with the n⁺⁺-type source regions 7 and the p⁺⁺-type contact regions 6. The source electrodes 18 are electrically insulated from the gate electrodes 13 by the interlayer insulating film 14. On the source electrodes 18, the source electrode pad (main electrode) 16 constituted by an Al—Si film is provided. The Al—Si film may be a film containing an Al—Si alloy. Between the source electrodes 18 and the interlayer insulating film 14, for example, a barrier metal 15 that prevents diffusion of metal atoms and the like in a direction from the source electrode pad (main electrode) 16 to the gate electrodes 13 may be provided. As another example, the barrier metal 15 may be omitted on the interlayer insulating film 14 to be provided only in contact holes or the barrier metal 15 may be omitted entirely. Further, as yet another example, the source electrodes 18 may be omitted and the barrier metal 15 may be in contact with the n⁺⁺-type source regions 7 and the p⁺⁺-type contact regions 6.

At an upper portion of the source electrode pad 16, a plating film 20 is provided. The plating film 20 may be selectively provided in an opening of a protective film (not depicted) provided at the upper portion of the source electrode pad 16. At the surface of the plating film 20, solder (not depicted) may be selectively provided. The plating film 20 is, for example, an Ni/Au plating film. At the solder, the pin electrodes (not depicted) constituting wiring for leading out potential of the source electrodes 18 are provided. The pin electrodes have pin-like shapes and are bonded upright to the source electrode pad 16. In FIG. 1, while only two metal-oxide-semiconductor insulated gate (MOS gate) structures are depicted in the active region 50, further MOS gate structures may be disposed in parallel.

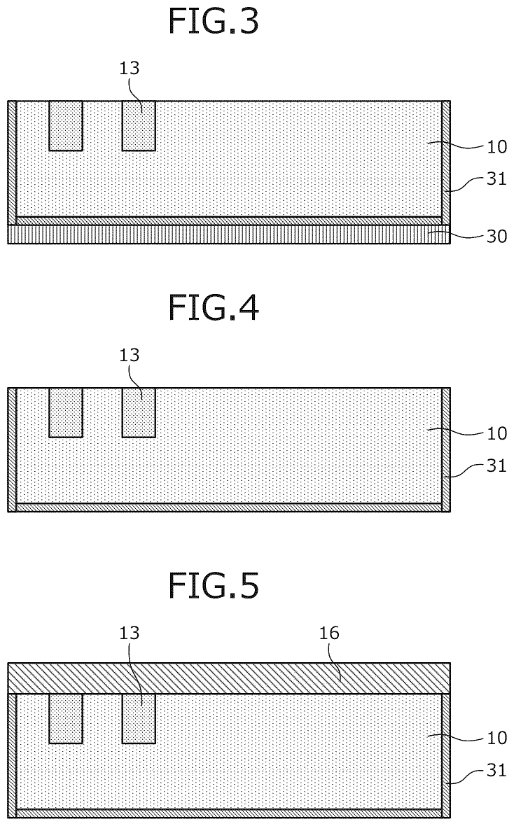

Next, the method of manufacturing the silicon carbide semiconductor device according to the embodiment is described. FIG. 2 is a flowchart of the method of manufacturing the silicon carbide semiconductor device according to the embodiment. FIGS. 3, 4, 5, 6, and 7 are cross-sectional views depicting states of the semiconductor device according to the embodiment during manufacture. In FIGS. 3 to 7, detailed depiction of the device structure in the silicon carbide substrate 10, the interlayer insulating film 14, and the barrier metal 15 is omitted.

First, the semiconductor device structure is formed as follows (step S1: first process). At the front surface of the n⁺-type silicon carbide substrate 1, the n⁻-type drift region 2 is grown by epitaxy. Next, at a front surface of the n⁻-type drift region 2, the p-type base region 5 is grown by epitaxy. The p-type base region 5 may be formed by ion implantation. Between the n⁻-type drift region 2 and the p-type base region 5, the n-type high-concentration region may be formed.

Next, p-type regions (the p⁺-type partial regions 4, the p⁺⁺-type contact regions 6, and the p⁺-type regions 26) are formed by photolithography and ion implantation of a p-type dopant, and the n⁺⁺-type source regions 7 are formed by photolithography and ion implantation of an n-type dopant. Next, a heat treatment for activating the dopants ion-implanted into the n⁻-type drift region 2 and the p-type base region 5 is performed. The heat treatment for dopant activation may be performed each time dopant ion-implantation is performed or may be performed for the dopants collectively.

Next, on the surface of the n⁺⁺-type source regions 7, a trench formation mask having predetermined openings is formed by photolithography, for example, using an oxide film. Next, the trenches 25, which penetrate through the n⁺⁺-type source regions 7 and the p-type base region 5 and reach the p⁺-type partial regions 4, are formed by dry etching. Next, the trench formation mask is removed.

After the trenches 25 are formed, isotropic etching for removing damage of the trenches 25 and sacrificial oxidation for rounding the bottoms of the trenches 25 and corners of the openings of the trenches 25 may be performed. Either the isotropic etching or the sacrificial oxidation alone may be performed. Further, the sacrificial oxidation may be performed after the isotropic etching. As a result, it becomes possible to produce a clean surface of silicon carbide and the corners may be rounded, whereby electric field may be suppressed from concentrating at the bottoms and openings of the trenches 25.

Next, the gate insulating film 11 is formed along the surface of the n⁺⁺-type source regions 7, the surface of the p⁺⁺-type contact regions 6, and the bottoms and sidewalls of the trenches 25. The gate insulating film 11 may be formed by thermal oxidation of a temperature of about 1300 degrees C. under a gas atmosphere containing oxygen. Further, the gate insulating film 11 may be formed by a deposition method by a chemical reaction such as high-temperature oxidation (HTO) for a high-temperature oxide film.

Next, on the gate insulating film 11, for example, a polysilicon doped with phosphorus is provided by a CVD method or the like. The polysilicon may be formed so as to be embedded in the trenches 25. The polysilicon is patterned by photolithography and left inside the trenches 25, thereby forming the gate electrodes 13 (step S2: second process).

An oxide film 31 is formed at the back surface and side surface of the silicon carbide substrate 10 by the thermal oxidation for forming the gate insulating film 11, and a back-surface polysilicon 30 is formed at the back surface of the silicon carbide substrate 10 by the polysilicon deposition for forming the gate electrodes 13. The state up to here is depicted in FIG. 3.

Next, the back-surface polysilicon 30 is removed (step S3: third process). Here, only the back-surface polysilicon 30 is removed by dry etching and the oxide film 31 is left. The state up to here is depicted in FIG. 4. In the dry etching for removing the back-surface polysilicon 30, the selectivity (etch rate of polysilicon/etch rate of SiO₂) is about 5, for example, is at least 4.5 but not more than 5.5, whereby the oxide film 31 is left and only the back-surface polysilicon 30 may be removed. Further, the selectivity may be enhanced by lowering RF output. Preferably, a thickness of the oxide film 31 is at least 50 nm but not more than 1000 nm to prevent plating deposition. The polysilicon may be further formed at sidewalls of the silicon carbide substrate 10 and in this instance, the polysilicon at the sidewalls is also removed.

Here, when plating treatment was performed on a wafer formed with the oxide film 31 having a thickness of 1000 nm, there was no growth of plating film at surfaces of the oxide film 31 (back surface, side surface), and it was confirmed that the oxide film 31 functions as a mask to prevent plating deposition.

Next, for example, phosphate glass of a thickness of about 1 μm is deposited so as to cover the gate insulating film 11 and the gate electrodes 13, thereby forming the interlayer insulating film 14. Next, the interlayer insulating film 14 and the gate insulating film 11 are patterned by photolithography, thereby forming contact holes exposing the n⁺⁺-type source regions 7 and the p⁺⁺-type contact regions 6. Next, in the contact holes and on the interlayer insulating film 14, a conductive film constituting the source electrodes 18 is formed by, for example, sputtering nickel. Next, a heat treatment of about 1000 degrees C. is performed, selectively causing reaction of the conductive film and the silicon carbide and thereafter, unreacted portions of the conductive film are selectively removed, leaving the source electrodes 18 only in the contact holes, with the n⁺⁺-type source regions 7 and the p⁺⁺-type contact regions 6 being in contact with the source electrodes 18.

Next, a Ti film is formed at surfaces of the source electrodes 18 and the interlayer insulating film 14 and thereafter, a TiN film is formed on the surface of the Ti film, thereby forming the barrier metal. Next, above the interlayer insulating film 14 and above the source electrodes 18 at the front surface of the silicon carbide semiconductor substrate, a metal film constituting the source electrode pad 16 is formed by, for example, a sputtering method. The Al—Si film is, for example, an aluminum alloy containing silicon at a ratio of 1% (Al—Si). The source electrode pad 16 may be formed by a metal film containing Al other than the Al film and the Al—Si film described. Next, the Al—Si film is patterned, forming the source electrode pad 16 constituting a surface electrode (step S4: fourth process). The state up to here is depicted in FIG. 5. When the surface electrode or the like is formed, the conductive film is prevented from being formed at the sidewalls and the back surface of the silicon carbide substrate 10. For example, in an instance in which the metal film is formed by sputtering, the back surface of the silicon carbide substrate 10 is fixed to a device stage, whereby the conductive film is not formed thereat and the side surface is also covered by a device cover, whereby the conductive film is not formed thereat.

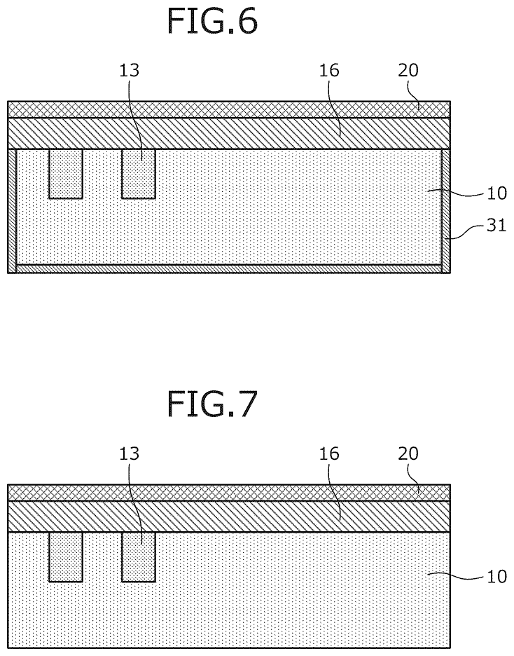

Next, the surface of the Al—Si film is subjected to a plating pretreatment in an etching tank or a zincate tank. Next, on the Al—Si film, the plating film 20 is formed by electroless Ni plating and Au plating (step S5: fifth process). The state up to here is depicted in FIG. 6.

Next, a glass support member is attached to the surface of the silicon carbide substrate 10; and the oxide film 31 at the back surface and side surface of the silicon carbide substrate 10 is removed by dry etching or wet etching (step S6). The state up to here is depicted in FIG. 7. When the oxide film 31 is present at the back surface, back griding (BG) of the wafer is difficult and therefore, the oxide film 31 at the back surface is removed before the BG process. Thus, the oxide film 31 at the side surface need not be removed.

As described in the embodiment, to prevent plating deposition, the oxide film 31 is left as is at the back surface and side surface of the silicon carbide substrate 10 when the plating film 20 is formed. As a result, there is no formation of the plating film 20 at exposed SiC portions of the silicon carbide substrate 10. Thus, protection of the back surface and the side surface by tape during plating becomes unnecessary, whereby labor and material costs may be reduced. Furthermore, in the case of protection by tape, while completely eliminating plating penetration into the tape is physically impossible, protection by the oxide film 31 is more effective at preventing plating deposition than protection by the tape, whereby quality may be enhanced.

Further, no outer peripheral tape is applied to the side surface of the silicon carbide substrate 10 and thus, a defect may be prevented in which an error occurs caused by a height difference during glass mounting of the WSS at a subsequent process, the height difference resulting from adhesive remaining when the outer peripheral tape is removed. Further, no back-surface tape is applied to the back surface of the silicon carbide substrate 10 and thus, a defect may be prevented in which a subsequent process proceeds with the back-surface tape being adhered as is, whereby during testing, conduction cannot be obtained and electrical characteristics cannot be measured.

Next, the front surface of the silicon carbide semiconductor substrate is covered and protected by a protective film (not depicted) and thereafter, the n⁺-type silicon carbide substrate 1 may be ground (BG) from the back side thereof, whereby the n⁺-type silicon carbide substrate 1 may be reduced in thickness to a product thickness.

Thereafter, by a general method, the gate pad (not depicted), a passivation film (not depicted), and the drain electrode 17 are formed. A portion of the source electrode pad 16 exposed by an opening of the passivation film constitutes a source pad. Thereafter, the semiconductor wafer is diced (cut) into individual chips, whereby the silicon carbide semiconductor device 70 depicted in FIG. 1 is completed.

As described, according to the embodiment, the plating film is formed with the oxide film left at the back surface and side surface of the silicon carbide substrate to prevent plating deposition thereat. As a result, no plating film is formed at exposed SiC portions of the silicon carbide substrate. Thus, protection of the back surface and the side surface by tape during plating becomes unnecessary, enabling labor and material costs to be reduced.

In the foregoing, the present disclosure may be variously modified within a range not departing from the spirit of the disclosure and in the embodiments, for example, dimensions and dopant concentrations, etc. of regions are variously set according to necessary specifications, etc. Further, in the embodiments, while the first conductivity type is assumed to be an n-type and the second conductivity type is assumed to be a p-type, the present disclosure is similarly implemented when the first conductivity type is a p-type and the second conductivity type is an n-type. Even in an instance of a silicon (Si) wafer, by a process flow similar to that for a SiC wafer, the oxide film mask is formed, whereby plating deposition may be prevented. Further, in the embodiment of the present disclosure, while a trench-type MOSFET is described as an example, without limitation hereto, application is possible to semiconductor devices of various configurations such as MOS-type semiconductor devices including insulated gate bipolar transistors (IGBTs), planar-type MOSFETs, etc., as well as diodes and the like.

According to the disclosure above, the plating film is formed with the oxide film left at the back surface and side surface of the silicon carbide substrate to prevent plating deposition thereat. As a result, no plating film is formed at exposed SiC portions of the silicon carbide substrate. Thus, protection of the back surface and the side surface by tape during plating becomes unnecessary, enabling labor and material costs to be reduced.

According to the method of manufacturing the semiconductor device according to the present disclosure, an effect is achieved in that during plating, protection by a back-surface tape and outer peripheral tape is unnecessary, labor and costs are reduced, and defects at processes after the plating process may be suppressed.

As described, the method of manufacturing the semiconductor device according to the present disclosure is useful for power semiconductor devices used in power converting equipment such as inverters, power source devices of various types of industrial machines, automobile igniters, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
preparing a semiconductor substrate having a front surface and a back surface opposite to each other, the semiconductor substrate being of a first conductivity type;
forming a device structure in the semiconductor substrate at the front surface;
performing thermal oxidation on the semiconductor substrate to form a gate insulating film and depositing a polysilicon on the semiconductor substrate to form a plurality of gate electrodes;
removing the polysilicon at the back surface of the semiconductor substrate while leaving an oxide film formed at the back surface and a side surface of the semiconductor substrate by the thermal oxidation;
forming a surface electrode on the device structure; and
forming a plating film on the surface electrode while continuing to leave the oxide film at the back surface and the side surface of the semiconductor substrate.

2. The method of manufacturing the semiconductor device, according to claim 1, further comprising after the forming the plating film,
removing the oxide film at the back surface and the side surface of the semiconductor substrate.

3. The method of manufacturing the semiconductor device, according to claim 1, wherein the oxide film at the back surface and the side surface of the semiconductor substrate has a thickness that is at least 50 nm but not more than 1000 nm.

4. The method of manufacturing the semiconductor device, according to claim 1, wherein the removing the polysilicon includes performing dry etching with a selectivity, defined by an etch rate of polysilicon to an etch rate of SiO₂, of at least 4.5 but not more than 5.5 to remove the polysilicon.

5. The method of manufacturing the semiconductor device, according to claim 1, wherein the forming the plating film includes performing an electroless plating process to form a nickel (Ni) plating film and a gold (Au) plating film as the plating film.
